(19) United States
(12) Patent Application Publication
(10) Pub. No.: US 2008/0185598 A1
(43) Pub. Date: Aug. 7, 2008

(54) LIGHT EMITTING DEVICE

(76) Inventors: Mei-Yuh LUO, Hsinchu (TW); Kuei-Fang CHEN, Hsinchu (TW); Han-Yu CHANG, Hsinchu (TW)

Correspondence Address: GREENBLUM & BERNSTEIN, P.L.C., 1950 ROLAND CLARKE PLACE, RESTON, VA, 20191, US

(21) Appl. No.: 12/024,378

(22) Filed: Feb. 1, 2008

(30) Foreign Application Priority Data
Feb. 6, 2007 (TW) 096104281

(51) Int. Cl. H01L 33/00

(52) U.S. Cl. 257/88; 257/99; 257/E33.066

(57) ABSTRACT

A light emitting device includes: a heat dissipating seat of a metallic material; a chip-mounting base of a semiconductor material attached to the heat dissipating seat; an insulator layer formed on the chip-mounting base; a bonding layer of a metal formed on the insulator layer; and a light emitting chip bonded to the bonding layer.

### CROSS-REFERENCE TO RELATED APPLICATION

This application claims priority of Taiwanese application no. 096104281, filed on Feb. 6, 2007.

### BACKGROUND OF THE INVENTION

1. Field of the Invention

This invention relates to a light emitting device, more particularly to a light emitting device including a light emitting chip mounted on a semiconductor base on a heat dissipating seat.

2. Description of the Related Art

U.S. Pat. No. 6,480,389 discloses a light emitting device including a metallic heat sink, an aluminum-based printed circuit board formed on the metallic heat sink and having an electrode contact, a metallic substrate bonded to the electrode contact through a solder and formed with a recess, an insulator layer formed on a recess-defining wall of the recess in the metallic substrate, and a light emitting chip received in the recess and attached to the insulator layer.

### SUMMARY OF THE INVENTION

An object of the present invention is to provide a light emitting device that has a high heat dissipating efficiency and that is easy to manufacture.

According to this invention, a light emitting device comprises: a heat dissipating seat of a metallic material; a chip-mounting base of a semiconductor material attached to the heat dissipating seat; an insulator layer formed on the chip-mounting base; a bonding layer of a metal formed on the insulator layer; and a light emitting chip bonded to the bonding layer.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic partly sectional view of the first preferred embodiment of a light emitting device according to this invention;

FIG. 2 is a schematic top view of the first preferred embodiment;

FIG. 3 is a schematic top view of the second preferred embodiment of the light emitting device according to this invention;

FIG. 4 is a schematic partly sectional view of the third preferred embodiment of the light emitting device according to this invention;

FIG. 5 is a schematic top view of the third preferred embodiment;

FIG. 6 is a schematic partly sectional view of the fourth preferred embodiment of the light emitting device according to this invention;

FIG. 7 is a schematic top view of the fourth preferred embodiment;

FIG. 8 is a schematic partly sectional view of the fifth preferred embodiment of the light emitting device according to this invention;

FIG. 9 is a schematic top view of the fifth preferred embodiment;

FIGS. 10A to 10C are schematic views illustrating consecutive steps of the preferred embodiment of a method for making a light emitting device according to this invention;

FIGS. 11A to 11C are schematic views illustrating further consecutive steps continued from the step of FIG. 10C for making the light emitting device of FIG. 2; and

FIGS. 12A to 12C are schematic views illustrating further consecutive steps continued from the step of FIG. 10C for making the light emitting device of FIG. 3.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

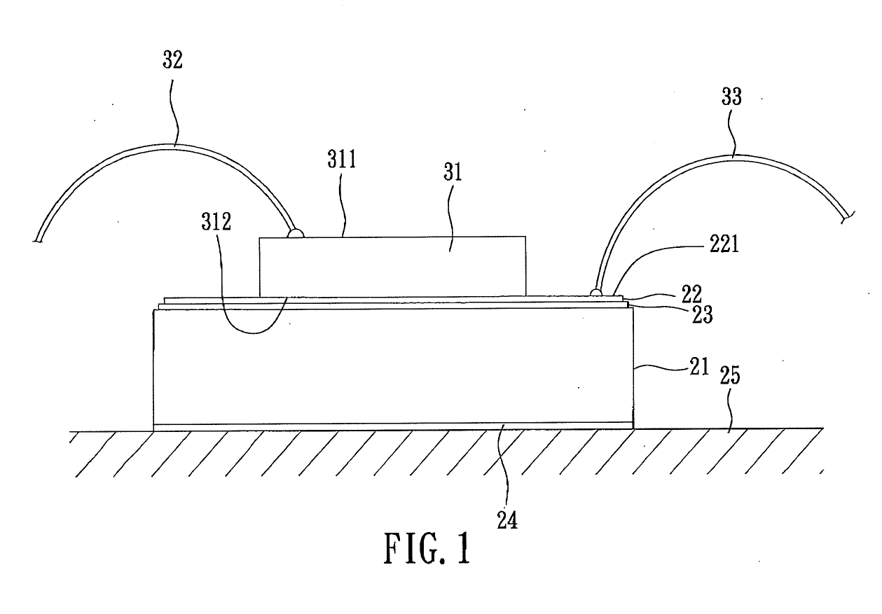

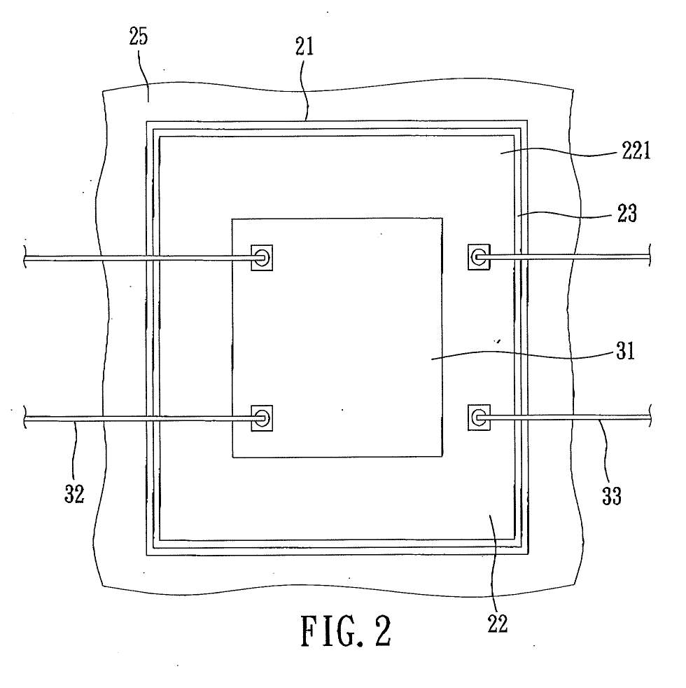

FIGS. 1 and 2 illustrate the first preferred embodiment of a light emitting device according to the present invention. The light emitting device includes: a heat dissipating seat 25 of a metallic material; a chip-mounting base 21 of a semiconductor material attached to the heat dissipating seat 25; an insulator layer 23 formed on the chip-mounting base 21; a first bonding layer 22 of a metal formed on the insulator layer 23; and a light emitting chip 31 bonded to the first bonding layer 22.

In this embodiment, the light emitting chip 31 has a bottom surface 312 bonded to the first bonding layer 22 through eutectic bonding, i.e., an eutectic layer (not shown) is formed at an interface between the bottom surface 312 of the light emitting chip 31 and the first bonding layer 22.

Preferably, the metal of the first bonding layer 22 is selected from the group consisting of Au, Cu, Ni, Ti, Pt, Ag, and Sn. Alternatively, the first bonding layer can be made from a metallic paste.

A second bonding layer 24 of a metallic material is disposed between and is bonded to the chip-mounting base 21 and the heat dissipating seat 25 through eutectic bonding, i.e., eutectic layers are formed at interfaces between the second bonding layer 24 and the chip-mounting base 21 and between the second bonding layer 24 and the heat dissipating seat 25. Alternatively, the second bonding layer 24 can be made from a metallic paste.

The heat dissipating seat 25 has an area larger than that of the chip-mounting base 21 so that the latter can be fully covered by the heat dissipating seat 25. The area of the chip-mounting base 21 is larger than that of the first bonding layer 22 so that latter can be fully covered by the chip-mounting base 21. The area of the first bonding layer 22 is larger than that of the light emitting chip 31 so that the bottom surface 312 of the latter can be fully covered by the first bonding layer 22. As such, heat generated by the light emitting chip 31 can be effectively dissipated through the heat dissipating seat 25.

The light emitting device further includes first and second bonding wires 32, 33 adapted to have respective positive and negative polarities and soldered respectively to a top surface 311 of the light emitting chip 31 and a peripheral end portion 221 of the first bonding layer 22 that is exposed from the light emitting chip 31.

Preferably, the semiconductor material of the chip-mounting base 21 is Si.

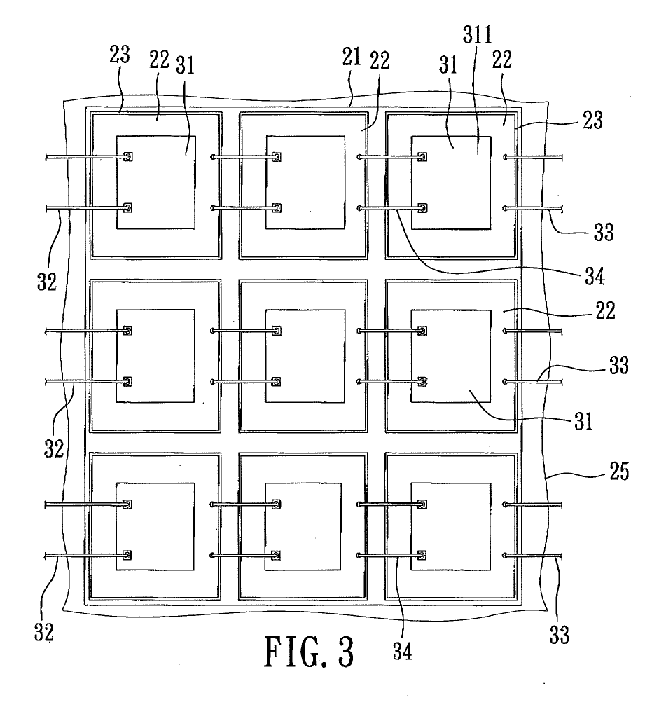

FIG. 3 illustrates the second preferred embodiment of the light emitting device according to this invention. The second preferred embodiment differs from the previous embodiment in that the light emitting device of the second preferred embodiment includes an array of the insulator layers 23 formed on the chip-mounting base 21, an array of the first bonding layers 22 formed on the insulator layers 23, respectively, and an array of the light emitting chips 31 bonded to the first bonding layers 22, respectively. In this embodiment, the array of the light emitting chips 31 includes a plurality of rows of the light emitting chips 31 which are connected in such a manner that the light emitting chips 31 of each one of the rows are electrically connected in a series connection manner, and that the rows of the light emitting chips 31 are electrically connected in a parallel connection manner. A plurality of intermediate bonding wires 34 are used to connect the light emitting chips 31 of each row. Each of the intermediate boding wires 34 is soldered to the top surface 311 of a respective one of the light emitting chips 31 and the first bonding layer 22 on an adjacent one of the light emitting chips 31.

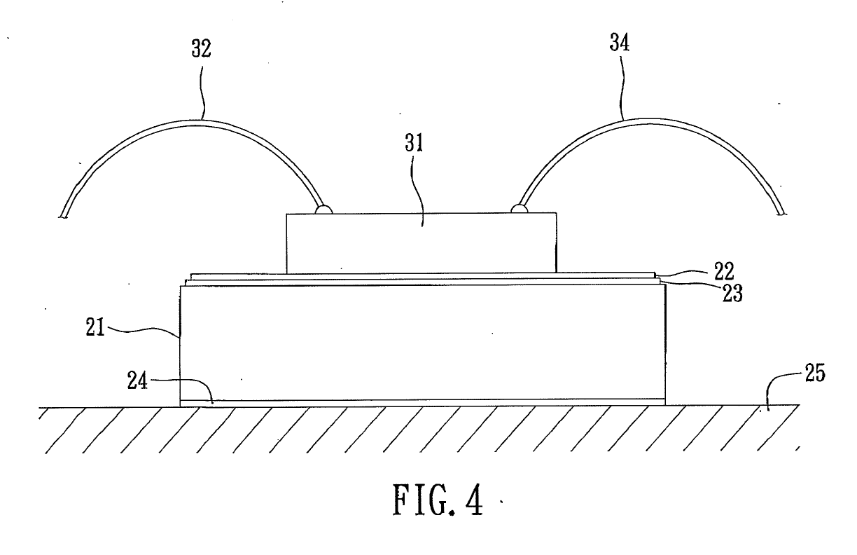

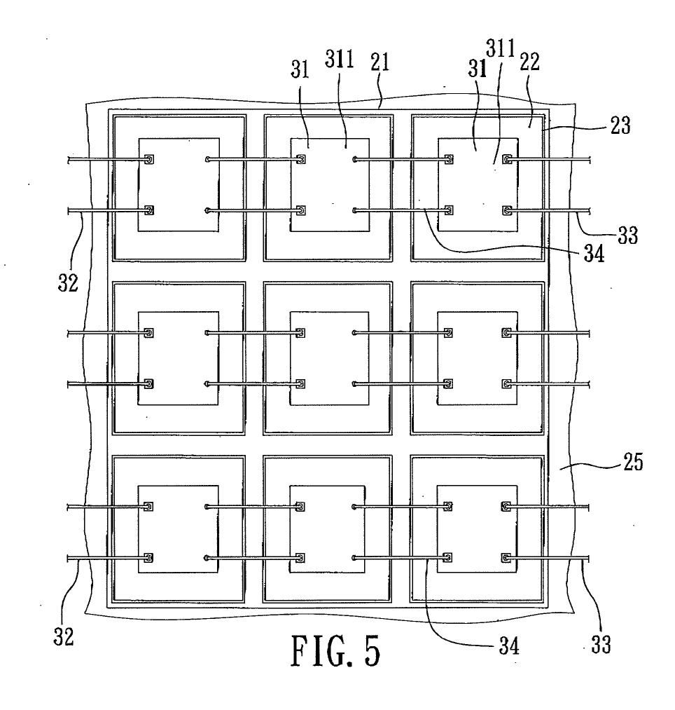

FIGS. 4 and 5 illustrate the third preferred embodiment of the light emitting device according to this invention. The third preferred embodiment differs from the second preferred embodiment in that the second bonding wire 33 is soldered to the top surface 311 of an endmost one of the light emitting chips 31 of each row, and that each of the intermediate bonding wires 34 is soldered to the top surfaces 311 of an adjacent pair of the light emitting chips 31.

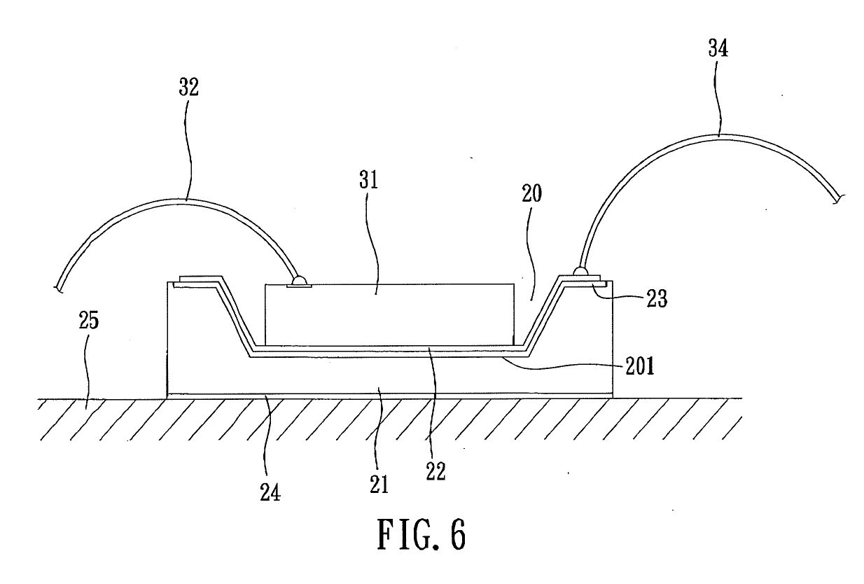

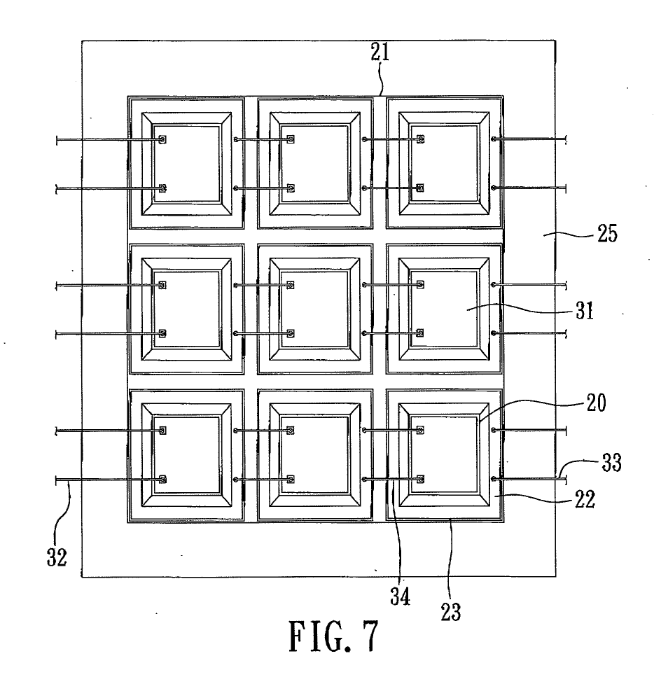

FIGS. 6 and 7 illustrate the fourth preferred embodiment of the light emitting device according to this invention. The fourth preferred embodiment differs from the second preferred embodiment in that the chip-mounting base 21 is formed with a plurality of chip-receiving recesses 20, each defined by a recess-defining wall 201, and that each of the light emitting chips 31 is received in a respective one of the chip-receiving recesses 20. Each of the insulator layers 23 is bonded to the recess-defining wall 201 of a respective one of the chip-receiving recesses 20.

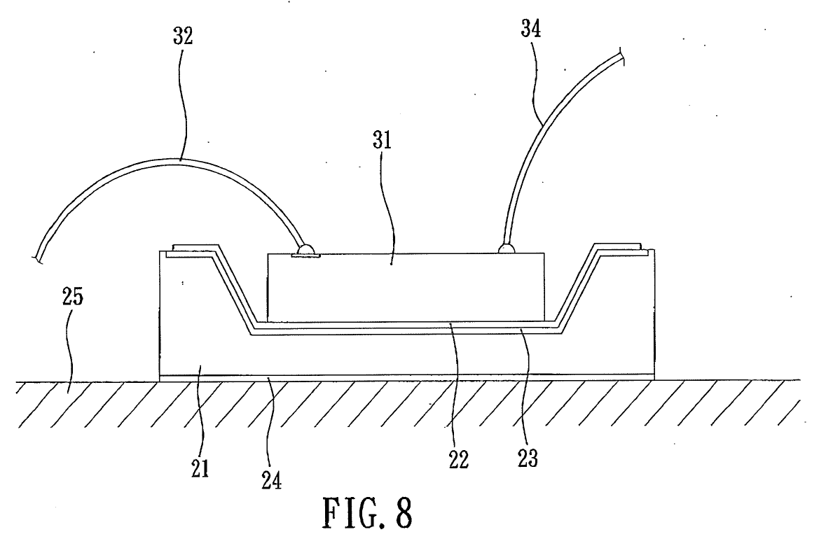

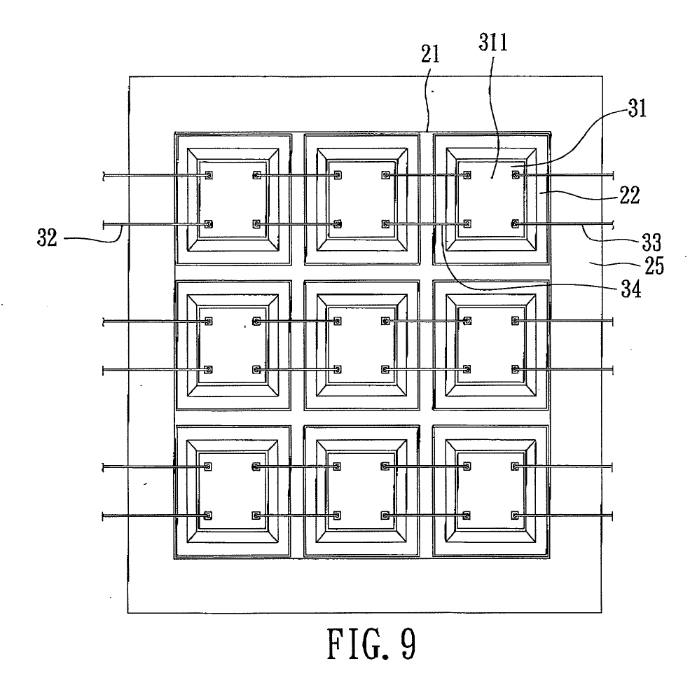

FIGS. 8 and 9 illustrate the fifth preferred embodiment of the light emitting device according to this invention. The fifth preferred embodiment differs from the fourth preferred embodiment in that the second bonding wire 33 is soldered to the top surface 311 of an endmost one of the light emitting chips 31 of each row, and that each of the intermediate bonding wires 34 is soldered to the top surfaces 311 of an adjacent pair of the light emitting chips 31.

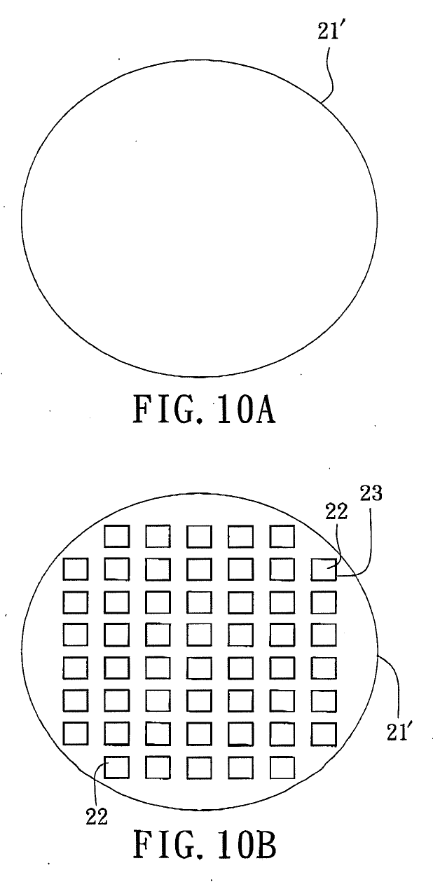

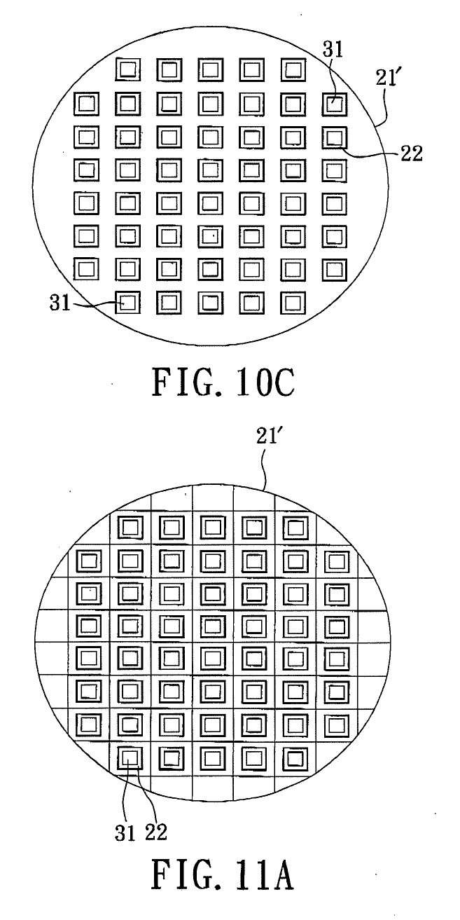

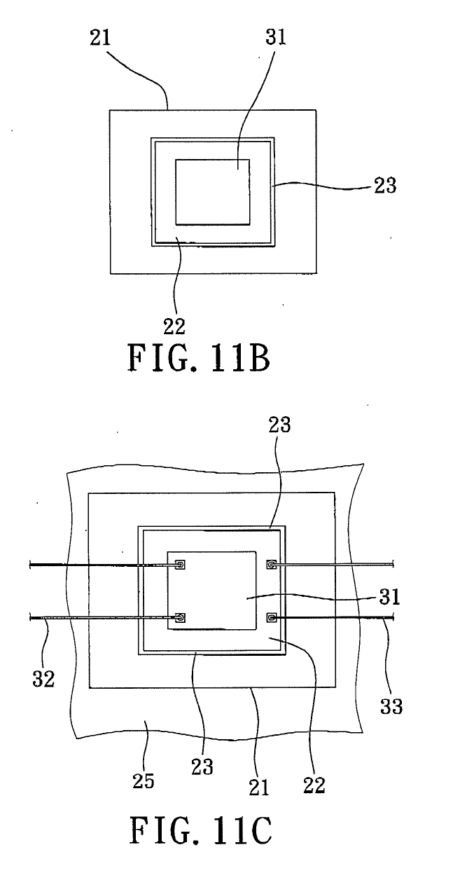

FIGS. 10A to 10C and 11A to 11C illustrate consecutive steps of the preferred embodiment of a method for making the light emitting device of FIG. 2 according to this invention. The method includes the steps of: preparing a wafer 21′ of the semiconductor material (see FIG. 10A); forming the array of the insulator layers 23 and the array of first bonding layers 22 on a front surface of the wafer 21′ (see FIG. 10B) through semiconductor processing techniques; forming the second bonding layer 24 on a back surface of the wafer 21′ (not shown); attaching the light emitting chips 31 on the first bonding layers 22, respectively (see FIG. 10C); bonding the light emitting chips 31 to the respective first bonding layers 22 through eutectic bonding techniques; cutting the wafer 21′ along predetermined cutting lines so as to form a plurality of the chip-mounting bases 21, each supporting a respective one of the light emitting chips 31 (see FIGS. 11A and 11B); bonding each chip-mounting base 21 to the heat dissipating seat 25 (see FIG. 11C); and wire bonding the light emitting chip 31 and the first bonding layer 22 so as to form the first and second bonding wires 32, 33 (see FIG. 11C).

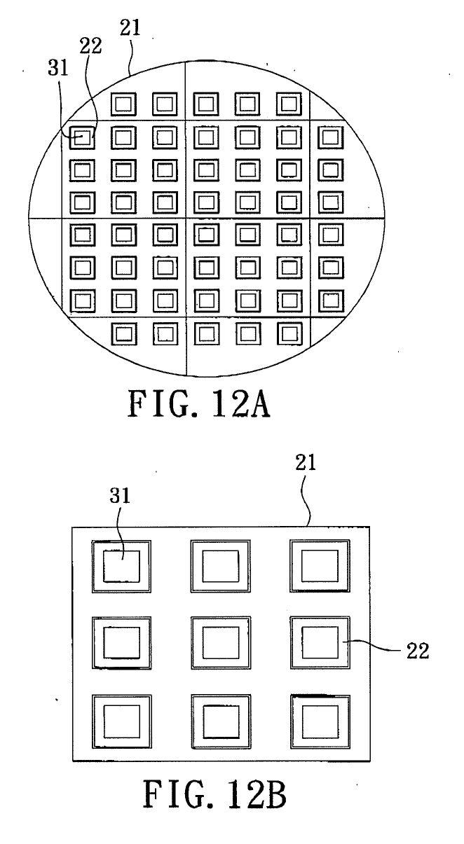

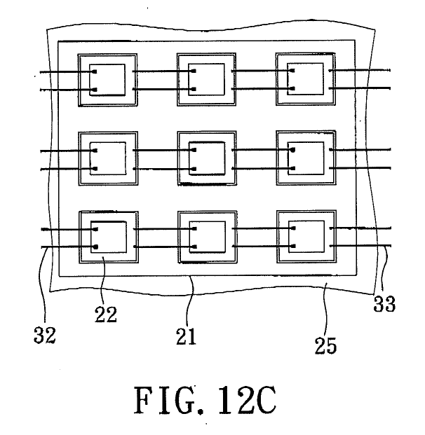

FIGS. 12A to 12C illustrate further consecutive steps continued from the step of FIG. 10C for making the light emitting device of FIG. 3. The method for making the light emitting device of FIG. 3 differs from that of FIG. 2 in that each of the chip-mounting bases 21 cut from the wafer 21′ (see FIGS. 12A to 12C) is formed with a plurality of the first bonding layers 22 and supports a plurality of light emitting chips 31 thereon.

By using the semiconductor material as the chip-mounting base 21 and by using semiconductor processing techniques to form the insulator layer(s) 23 and the first bonding layer(s) 22, the contacting qualities between the first bonding layer(s) 22 and the light emitting chip(s) 31 and between the chip-mounting base 21 and the heat dissipating seat 25 can be enhanced, thereby enhancing the heat dissipating efficiency of the light emitting device of this invention.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A light emitting device comprising:
a heat dissipating seat of a metallic material;
a chip-mounting base of a semiconductor material attached to said heat dissipating seat;
an insulator layer formed on said chip-mounting base;
a first bonding layer of a metal formed on said insulator layer; and
a light emitting chip bonded to said first bonding layer.

2. The light emitting device of claim 1, wherein said light emitting chip has a bottom surface bonded to said first bonding layer through eutectic bonding.

3. The light emitting device of claim 2, wherein said metal of said first bonding layer is selected from the group consisting of Au, Cu, Ni, Ti, Pt, Ag, and Sn.

4. The light emitting device of claim 1, further comprising a second bonding layer disposed between and bonded to said chip-mounting base and said heat dissipating seat through eutectic bonding.

5. The light emitting device of claim 1, wherein said light emitting chip has top and bottom surfaces, said bottom surface of said light emitting chip being bonded to said first bonding layer through eutectic bonding, said light emitting device further comprising first and second bonding wires soldered respectively to said top surface of said light emitting chip and said first bonding layer.

6. The light emitting device of claim 1, wherein said light emitting chip has top and bottom surfaces, said bottom surface of said light emitting chip being bonded to said first bonding layer through eutectic bonding, said light emitting device further comprising first and second bonding wires soldered to said top surface of said light emitting chip.

7. The light emitting device of claim 1, wherein said chip-mounting base is formed with a chip-receiving recess defined by a recess-defining wall, said light emitting chip being received in said chip-receiving recess, said insulator layer being bonded to said recess-defining wall.

8. The light emitting device of claim 1, wherein said semiconductor material of said chip-mounting base is Si.

9. A light emitting device comprising:
a heat dissipating seat of a metallic material;
a chip-mounting base of a semiconductor material attached to said heat dissipating seat;
an array of insulator layers formed on said chip-mounting base;
an array of first bonding layers of a metal formed on said insulator layers, respectively; and
an array of light emitting chips bonded to said first bonding layers, respectively;
wherein said array of said light emitting chips includes a plurality of rows of said light emitting chips, said light emitting chips of each one of said rows being electrically connected in a series connection manner, said rows of said light emitting chips being electrically connected in a parallel connection manner.

10. The light emitting device of claim 9, wherein said chip-mounting base is formed with a plurality of chip-receiving recesses, each of said light emitting chips being received in a respective one of said chip-receiving recesses.

11. The light emitting device of claim 9, wherein said semiconductor material of said chip-mounting base is Si.
